(19) United States
(12) Patent Application Publication
(10) Pub. No.: US 2026/0173519 A1
(43) Pub. Date: Jun. 18, 2026

(54) MULTI-STACK SEMICONDUCTOR DEVICE

(71) Applicant: Samsung Electronics Co., Ltd., Suwon-si (KR)

(72) Inventors: Jisoo Park, Suwon-si (KR); Byungsung Kim, Suwon-si (KR); Jinwoo Jeong, Suwon-si (KR); Youngkwan Jo, Suwon-si (KR); Kwanyoung Chun, Suwon-si (KR)

(21) Appl. No.: 19/416,580

(22) Filed: Dec. 11, 2025

(30) Foreign Application Priority Data
Dec. 17, 2024 (KR) 10-2024-0188866

(51) Int. Cl. H10D 84/85; H10D 84/01

(52) U.S. Cl. CPC H10D 84/856; H10D 84/0186; H10D 84/851

(57) ABSTRACT

An example of a multi-stack semiconductor device includes first and second lower source/drain regions, first and second lower contact structures disposed on lower surfaces of the first and second lower source/drain regions, respectively, first and second upper source/drain regions disposed to be vertically spaced apart from the first and second lower source/drain regions, respectively, first and second upper contacts disposed on upper surfaces of the first and second upper source/drain regions, respectively, a vertical conductive via vertically connecting the first lower contact structure to the first upper contact, and a dielectric cover structure disposed between the first upper source/drain region and the first upper contact.

### CROSS-REFERENCE TO RELATED APPLICATION

This application is based on and claims priority under 35 U.S.C. § 119 to Korean Patent Application No. 10-2024-0188866, filed on Dec. 17, 2024, in the Korean Intellectual Property Office, the disclosure of which is incorporated by reference herein in its entirety.

### BACKGROUND

Recently, down-scaling of semiconductor devices has rapidly progressed. In addition, because a semiconductor device requires not only a quick operating speed but also the accuracy of an operation, the structure of transistors included in the semiconductor device is desired to be optimized.

### SUMMARY

According to high integration of semiconductor devices, a semiconductor device can include multi-gate-structured three-dimensional transistors. For example, a three-dimensional transistor may be implemented in a form in which an active pin is surrounded by a gate.

The present disclosure provides a multi-stack semiconductor device including a field-effect transistor with improved integration and electrical performance.

The problems to be solved by the technical idea of the present disclosure are not limited to the problem mentioned above, and other problems could be clearly understood by those of ordinary skill in the art from the description below.

According to an aspect of the present disclosure, a multi-stack semiconductor device includes first and second lower source/drain regions, first and second lower contact structures disposed on lower surfaces of the first and second lower source/drain regions, respectively, first and second upper source/drain regions disposed to be vertically spaced apart from the first and second lower source/drain regions, respectively, first and second upper contacts disposed on upper surfaces of the first and second upper source/drain regions, respectively, a vertical conductive via vertically connecting the first lower contact structure to the first upper contact, and a dielectric cover structure disposed between the first upper source/drain region and the first upper contact, wherein the first upper source/drain region and the first upper contact overlap but are not in contact with each other in a vertical direction and a horizontal direction, and the second upper source/drain region and the second upper contact overlap and are in contact with each other in the vertical direction and the horizontal direction.

According to another aspect of the present disclosure, a multi-stack semiconductor device includes first and second lower source/drain regions, first and second lower contact structures disposed on lower surfaces of the first and second lower source/drain regions, respectively, first and second upper source/drain regions disposed to be vertically spaced apart from the first and second lower source/drain regions, respectively, first and second upper contacts disposed on upper surfaces of the first and second upper source/drain regions, respectively, a vertical conductive via vertically connecting the first lower contact structure to the first upper contact, and a dielectric cover structure disposed between the first upper source/drain region and the first upper contact, wherein the first upper source/drain region, the dielectric cover structure, and the first upper contact overlap each other in a horizontal direction at a same vertical level.

According to another aspect of the present disclosure, a multi-stack semiconductor device includes first and second lower source/drain regions, first and second lower contacts disposed on lower surfaces of the first and second lower source/drain regions, respectively, first and second lower contact merged lines disposed on lower surfaces of the first and second lower contacts, first and second upper source/drain regions disposed to be vertically spaced apart from the first and second lower source/drain regions, respectively, first and second upper contacts disposed on upper surfaces of the first and second upper source/drain regions, respectively, a vertical conductive via vertically connecting the first lower contact merged line to the first upper contact, a front wiring line connecting the first upper contact to the second upper contact, and a dielectric cover structure disposed between the first upper source/drain region and the first upper contact, wherein the first lower source/drain region is electrically connected to the second upper source/drain region via the first lower contact, the first lower contact merged line, the vertical conductive via, the first upper contact, the front wiring line, and the second upper contact in order, and the first lower source/drain region is not electrically connected to the first upper source/drain region by the dielectric cover structure.

### BRIEF DESCRIPTION OF THE DRAWINGS

Implementations of the present disclosure will be more clearly understood from the following detailed description taken in conjunction with the accompanying drawings in which:

FIG. 1 is a perspective view illustrating a multi-stack semiconductor device according to an implementation;

FIG. 2 is a cross-sectional view illustrating both a cross-section taken along line X1-X1′ of FIG. 1 and a cross-section taken along line X2-X2′ of FIG. 1;

FIG. 3 is a cross-sectional view illustrating both a cross-section taken along line X3-X3′ of FIG. 1 and a cross-section taken along line X4-X4′ of FIG. 1;

FIG. 4 is a top layout of FIG. 1 in a top view;

FIG. 5 is a bottom layout of FIG. 1 in a bottom view;

FIGS. 6 and 7 are cross-sectional views illustrating a multi-stack semiconductor device according to another implementation; and

FIGS. 8 to 14 are cross-sectional views illustrating, in a process order, a method of manufacturing a multi-stack semiconductor device, according to an implementation.

### DETAILED DESCRIPTION

Hereinafter, implementations are described in detail with reference to the accompanying drawings.

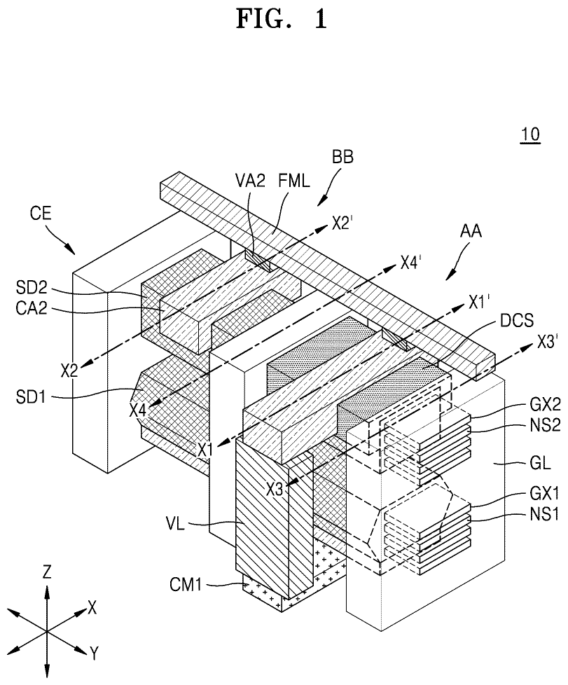

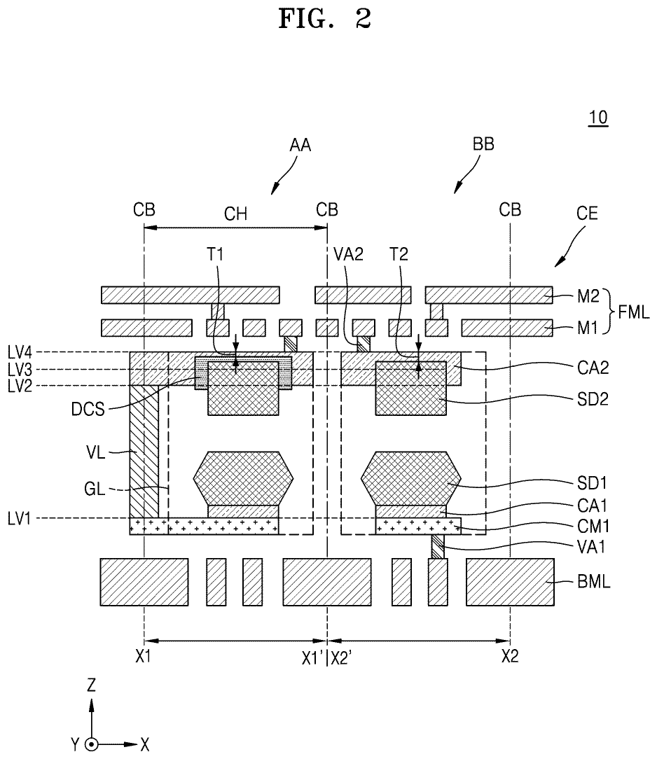

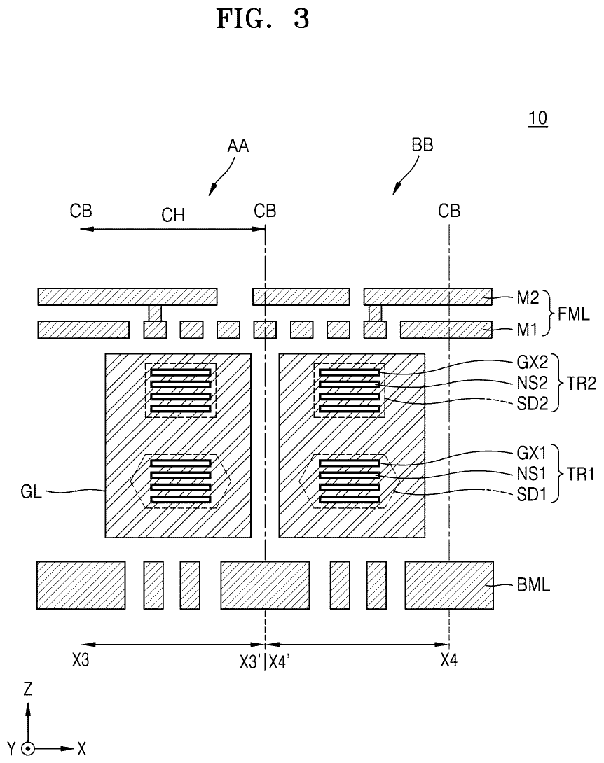

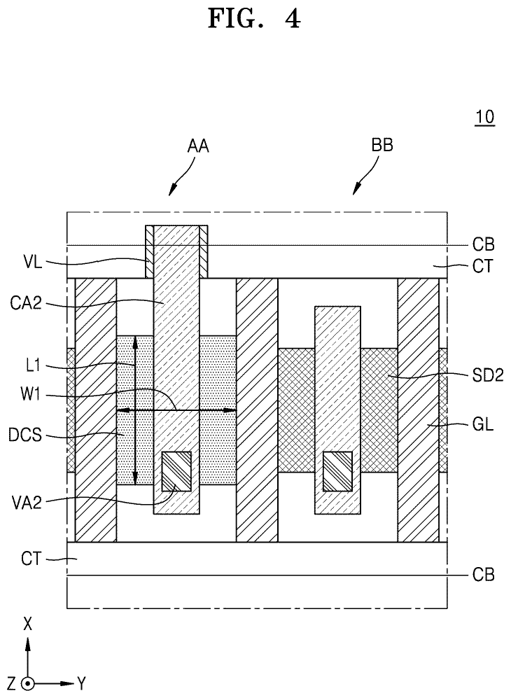

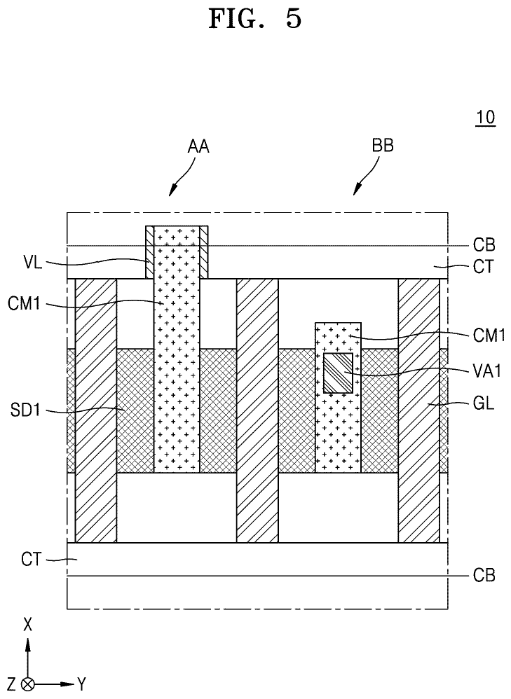

FIG. 1 is a perspective view illustrating a multi-stack semiconductor device 10 according to an implementation. FIG. 2 is a cross-sectional view illustrating both a cross-section taken along line X1-X1′ of FIG. 1 and a cross-section taken along line X2-X2′ of FIG. 1. FIG. 3 is a cross-sectional view illustrating both a cross-section taken along line X3-X3′ of FIG. 1 and a cross-section taken along line X4-X4′ of FIG. 1. FIG. 4 is a top layout of FIG. 1 in a top view. FIG. 5 is a bottom layout of FIG. 1 in a bottom view.

Referring to FIGS. 1 to 5, the multi-stack semiconductor device 10 of the present disclosure may include a plurality of cells CE, and each cell CE may include a plurality of lower transistors TR1 and a plurality of upper transistors TR2.

In the multi-stack semiconductor device 10, the plurality of upper transistors TR2 may be disposed at a vertical level higher than that of the plurality of lower transistors TR1 in a vertical direction Z. Each of the plurality of cells CE may be one of various types of logic cells included in a logic circuit. Each of the plurality of cells CE may be identified by a cell boundary CB, and the distance between two adjacent cell boundaries CB in a first horizontal direction X, that is, the width of a cell CE, may be referred to as a cell height CH.

The multi-stack semiconductor device 10 may further include a front wiring line FML disposed at a vertical level higher than that of the plurality of upper transistors TR2 and a back wiring line BML disposed at a vertical level lower than that of the plurality of lower transistors TR1. In some implementations, the front wiring line FML may be configured to apply a signal voltage to the plurality of lower transistors TR1 and the plurality of upper transistors TR2, and the back wiring line BML may be configured to apply a power source voltage and/or a ground voltage to the plurality of lower transistors TR1 and the plurality of upper transistors TR2.

The multi-stack semiconductor device 10 may include a field-effect transistor (FET) device including nanosheets. However, the technical idea of the present disclosure is not limited thereto, and the multi-stack semiconductor device 10 may include a two-dimensional material-based FET device, such as a planar FET device, a gate-all-around-type FET device, a finFET device, or a metal oxide semiconductor (MOS) semiconductor gate electrode, and the like.

Each of the plurality of lower transistors TR1 may include a plurality of lower nanosheets NS1 stacked in the vertical direction Z, a lower source/drain region SD1 connected to the plurality of lower nanosheets NS1, a plurality of lower gate dielectric layers GX1 surrounding the plurality of lower nanosheets NS1, respectively, a lower contact CA1 disposed on the lower surface of the lower source/drain region SD1, and a lower contact merged line CM1 disposed on the lower surface of the lower contact CA1. Herein, the lower contact CA1 and the lower contact merged line CM1 may be integrally referred to as a lower contact structure.

Each of the plurality of upper transistors TR2 may include a plurality of upper nanosheets NS2 stacked in the vertical direction Z, an upper source/drain region SD2 connected to the plurality of upper nanosheets NS2, a plurality of upper gate dielectric layers GX2 surrounding the plurality of upper nanosheets NS2, respectively, and an upper contact CA2 disposed on the upper surface of the upper source/drain region SD2.

Herein, a lower transistor TR1 and an upper transistor TR2 may share a gate line GL.

In some implementations, each of the plurality of lower transistors TR1 may be a p-type MOS (PMOS) transistor, and each of the plurality of upper transistors TR2 may be an n-type MOS (NMOS) transistor. In some implementations, each of the plurality of lower transistors TR1 may be an NMOS transistor, and each of the plurality of upper transistors TR2 may be a PMOS transistor.

In some implementations, each of the plurality of lower transistors TR1 may be an NMOS transistor having a first threshold voltage, and each of the plurality of upper transistors TR2 may be an NMOS transistor having a second threshold voltage that is different from the first threshold voltage. In some implementations, each of the plurality of lower transistors TR1 may be a PMOS transistor having a first threshold voltage, and each of the plurality of upper transistors TR2 may be a PMOS transistor having a second threshold voltage that is different from the first threshold voltage.

Each of the plurality of lower nanosheets NS1 and the plurality of upper nanosheets NS2 may include a Group IV semiconductor material, such as silicon (Si) or germanium (Ge), a Group IV-IV compound semiconductor material, such as SiGe or silicon carbide (SiC), or a Group III-V compound semiconductor material, such as gallium arsenide (GaAs), indium arsenide (InAs), or indium phosphide (InP).

The lower source/drain region SD1 may be connected to both ends of the plurality of lower nanosheets NS1. The lower source/drain region SD1 may have an upper surface at a vertical level higher than that of the upper surface of the uppermost lower nanosheet NS1 and have a lower surface at a vertical level lower than that of the lower surface of the lowermost lower nanosheet NS1. In some implementations, the lower source/drain region SD1 may be made of a doped SiGe layer, a doped Ge layer, a doped SiC layer, or a doped indium gallium arsenide (InGaAs) layer but is not limited thereto.

The upper source/drain region SD2 may be connected to both ends of the plurality of upper nanosheets NS2. The upper source/drain region SD2 may be spaced apart from the lower source/drain region SD1 in the vertical direction Z at a position vertically overlapping the lower source/drain region SD1. The upper source/drain region SD2 may have an upper surface at a vertical level higher than that of the upper surface of the uppermost upper nanosheet NS2 and have a lower surface at a vertical level lower than that of the lower surface of the lowermost upper nanosheet NS2. In some implementations, the upper source/drain region SD2 may be made of a doped SiGe layer, a doped Ge layer, a doped SiC layer, or a doped InGaAs layer but is not limited thereto.

In some implementations, the lower source/drain region SD1 may include a material that is different from that of the upper source/drain region SD2. Accordingly, the lower source/drain region SD1 may be formed in a shape that is different from the shape of the upper source/drain region SD2.

The gate line GL may be elongated in the first horizontal direction X while surrounding the plurality of lower nanosheets NS1 and the plurality of upper nanosheets NS2, and gate lines GL may be spaced apart from each other in a second horizontal direction Y. The plurality of lower gate dielectric layers GX1 may be between the gate line GL and the plurality of lower nanosheets NS1, and the plurality of upper gate dielectric layers GX2 may be between the gate line GL and the plurality of upper nanosheets NS2. The gate line GL may be cut in the first horizontal direction X by a gate cut CT extending in the second horizontal direction Y.

In some implementations, the gate line GL may include doped polysilicon, a metal, conductive metal nitride, conductive metal carbide, conductive metal silicide, or a combination thereof and may be made of, for example, aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum nitride (TiAlN), tantalum carbonitride (TaCN), tantalum carbide (TaC), tantalum silicon nitride (TaSiN), or a combination thereof but is not limited thereto.

In some implementations, the gate line GL may include a work function metal-containing layer (not shown) and a gap-fill metal layer (not shown). The work function metal-containing layer may include at least one metal selected from among Ti, W, ruthenium (Ru), niobium (Nb), Mo, hafnium (Hf), Ni, Co, platinum (Pt), yttrium (Yb), terbium (Tb), dysprosium (Dy), erbium (Er), and palladium (Pd). The gap-fill metal layer may include a W layer or an Al layer.

In some implementations, a lower gate dielectric layer GX1 and an upper gate dielectric layer GX2 may include a silicon oxide layer, a silicon oxynitride layer, a high-k dielectric layer having a higher dielectric constant than the silicon oxide layer, or a combination thereof. The high-k dielectric layer may be made of metal oxide or metal oxynitride. For example, the high-k dielectric layer usable for the lower gate dielectric layer GX1 and the upper gate dielectric layer GX2 may made of hafnium dioxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO₂), alumina (Al₂O₃), or a combination thereof but is not limited thereto.

The lower contact structure may be disposed on the lower surface of the lower source/drain region SD1. The lower contact structure may include the lower contact CA1 and the lower contact merged line CM1. The upper contact CA2 may be disposed on the upper surface of the upper source/drain region SD2. In some implementations, the lower contact CA1, the lower contact merged line CM1, and the upper contact CA2 may include at least one of W, cobalt (Co), Mo, nickel (Ni), Ru, Cu, Al, Ti, TiN, Ta, TaN, titanium silicon nitride (TiSiN), titanium silicide (TiSi), and tungsten silicide (WSi).

An intermediate dielectric layer (not shown) may be disposed between the lower transistor TR1 and the upper transistor TR2. The lower surface of the upper source/drain region SD2 may be on the upper surface of the intermediate dielectric layer. The upper surface of the lower source/drain region SD1 may be beneath the lower surface of the intermediate dielectric layer.

A vertical conductive via VL may extend lengthwise in the vertical direction Z between the lower contact merged line CM1 and the upper contact CA2 to electrically connect the lower contact merged line CM1 to the upper contact CA2. By doing this, the vertical conductive via VL may transfer a signal voltage, a power source voltage, a ground voltage, or the like from the front wiring line FML and the back wiring line BML to the lower transistor TR1 and the upper transistor TR2.

A lower via VA1 may electrically connect the lower contact merged line CM1 to the back wiring line BML. The back wiring line BML may include a plurality of wiring lines disposed at different vertical levels and a plurality of conductive vias connecting therebetween. Although not shown in FIGS. 1 to 5, a plurality of dielectric layers may surround the back wiring line BML.

An upper via VA2 may electrically connect the upper contact CA2 to the front wiring line FML. The front wiring line FML may include a plurality of wiring lines disposed at different vertical levels and a plurality of conductive vias connecting therebetween. In some implementations, the front wiring line FML may include a first wiring line M1 and a second wiring line M2 that is disposed above the first wiring line M1, but is not limited thereto. Although not shown in FIGS. 1 to 5, a plurality of dielectric layers may surround the front wiring line FML.

In some implementations, the vertical conductive via VL, the lower via VA1, and the upper via VA2 may include at least one of W, Co, Mo, Ni, Ru, Cu, Al, Ti, TiN, Ta, TaN, TiSiN, TiSi, and WSi.

Hereinafter, to more particularly describe the multi-stack semiconductor device 10 of the present disclosure, components located in an area AA of FIGS. 1 to 5 are referred to as first components, and components located in an area BB of FIGS. 1 to 5 are referred to as second components. For example, the lower source/drain region SD1 located in the area AA of FIGS. 1 to 5 is referred to as a first lower source/drain region SD1, and the lower source/drain region SD1 located in the area BB of FIGS. 1 to 5 is referred to as a second lower source/drain region SD1.

The multi-stack semiconductor device 10 may include the first and second lower source/drain regions SD1, first and second lower contacts CA1 disposed on the lower surfaces of the first and second lower source/drain regions SD1, respectively, and first and second lower contact merged lines CM1 disposed on the lower surfaces of the first and second lower contacts CA1, respectively.

In addition, the multi-stack semiconductor device 10 may include first and second upper source/drain regions SD2 vertically spaced apart from the first and second lower source/drain regions SD1, respectively, and first and second upper contacts CA2 disposed on the upper surfaces of the first and second upper source/drain regions SD2, respectively. That is, the multi-stack semiconductor device 10 of the present disclosure may include the lower contact merged line CM1 but not include an upper contact merged line. This feature is described below.

In addition, the multi-stack semiconductor device 10 may include the vertical conductive via VL vertically connecting the first lower contact merged line CM1 to the first upper contact CA2 and the front wiring line FML connecting the first upper contact CA2 to the second upper contact CA2. For connection to the vertical conductive via VL, the length of the first upper contact CA2 in the first horizontal direction X may be greater than the length of the second upper contact CA2 in the first horizontal direction X.

In the multi-stack semiconductor device 10 of the present disclosure, a dielectric cover structure DCS may be disposed only between the first upper source/drain region SD2 and the first upper contact CA2 located in the area AA of FIGS. 1 to 5. In other words, the dielectric cover structure DCS may not be disposed between the second upper source/drain region SD2 and the second upper contact CA2 located in the area BB of FIGS. 1 to 5.

The dielectric cover structure DCS may be located such that the dielectric cover structure DCS overlaps the first upper source/drain region SD2 and the second upper contact CA2 in the first horizontal direction X at a same vertical level (e.g., LV3). In some implementations, the dielectric cover structure DCS may include a dielectric material, such as silicon nitride, silicon carbide, or silicon carbonitride, having an etching selectivity with respect to silicon oxide.

In the multi-stack semiconductor device 10 of the present disclosure, a vertical level LV2 of the lowermost surface of the first upper contact CA2 may be lower than the vertical level of the uppermost surface of the first upper source/drain region SD2, and a vertical level LV4 of the uppermost surface of the first upper contact CA2 may be higher than the vertical level of the uppermost surface of the first upper source/drain region SD2.

Particularly, the first upper contact CA2 may include a lower surface having an uneven structure, which covers both side surfaces and the upper surface of the dielectric cover structure DCS, and the second upper contact CA2 may include a lower surface having an uneven structure, which covers both side surfaces and the upper surface of the second upper source/drain region SD2. Herein, a first thickness T1 of a portion of the first upper contact CA2 overlapping the first upper source/drain region SD2 in the vertical direction Z may be less than a second thickness T2 of a portion of the second upper contact CA2 overlapping the second upper source/drain region SD2 in the vertical direction Z. This is because the dielectric cover structure DCS is disposed between the first upper source/drain region SD2 and the first upper contact CA2.

As such, because the dielectric cover structure DCS is disposed between the first upper source/drain region SD2 and the first upper contact CA2, the first upper source/drain region SD2 and the first upper contact CA2 may overlap but not be in contact with each other in the vertical direction Z and the first horizontal direction X. However, the second upper source/drain region SD2 and the second upper contact CA2 may overlap and be in contact with each other in the vertical direction Z and the first horizontal direction X.

Due to the dielectric cover structure DCS, the first lower source/drain region SD1 may not be electrically connected to the first upper source/drain region SD2. That is, the first lower source/drain region SD1 may be electrically connected to the second upper source/drain region SD2 via the first lower contact CA1, the first lower contact merged line CM1, the vertical conductive via VL, the first upper contact CA2, the front wiring line FML, and the second upper contact CA2 in order.

In the multi-stack semiconductor device 10 of the present disclosure, in the first horizontal direction X, the first upper contact CA2 may extend lengthwise, and a length L1 of the dielectric cover structure DCS may be less than the length of the first upper contact CA2 and greater than the length of the first upper source/drain region SD2. In addition, in the second horizontal direction Y, a width W1 of the dielectric cover structure DCS may be greater than the width of the first upper contact CA2 and less than the width of the first upper source/drain region SD2.

Herein, the vertical level LV2 of the uppermost surface of the vertical conductive via VL may be lower than the vertical level of the uppermost surface of the first upper source/drain region SD2 and higher than the vertical level of the lowermost surface of the first upper source/drain region SD2, and a vertical level LV1 of the lowermost surface of the vertical conductive via VL may be lower than the lowermost surface of the first lower source/drain region SD1. That is, the uppermost surface of the vertical conductive via VL may be in direct contact with the lowermost surface of the first upper contact CA2, and the lowermost surface of the vertical conductive via VL may be in direct contact with the uppermost surface of the first lower contact merged line CM1.

In addition, the width W1 of the dielectric cover structure DCS may be less than or equal to the gap between a pair of gate lines GL. For the gate line GL between the first upper source/drain region SD2 and the second upper source/drain region SD2, one sidewall of the gate line GL may face the dielectric cover structure DCS, and the other sidewall of the gate line GL may not face the dielectric cover structure DCS. Alternatively, the one sidewall of the gate line GL may be in contact with the dielectric cover structure DCS, and the other sidewall of the gate line GL may not be in contact with the dielectric cover structure DCS.

According to the length L1 and the width W1 of the dielectric cover structure DCS described above, the dielectric cover structure DCS may completely isolate the first upper source/drain region SD2 from the first upper contact CA2.

In the multi-stack semiconductor device 10 of the present disclosure, a cross-section of each of the first and second upper source/drain regions SD2 may have a quadrangular shape (e.g., a rectangular shape), and the dielectric cover structure DCS may be conformally formed to cover a portion of both side surfaces and all of the upper surface of the rectangular shape of the first upper source/drain region SD2.

As described above, because the shape of the first and second upper source/drain regions SD2 may be different from the shape of the first and second lower source/drain regions SD1, a cross-section of each of the first and second lower source/drain regions SD1 may have a hexagonal shape. However, in the multi-stack semiconductor device 10 of the present disclosure, the shape of the first and second lower source/drain regions SD1 and the shape of the first and second upper source/drain regions SD2 are not limited thereto.

In general, to prevent an electrical connection between the first upper source/drain region SD2 and the first lower source/drain region SD1 in the multi-stack semiconductor device 10, a first upper contact merged line needs to be formed so as to be spaced apart by a considerable distance from the first upper source/drain region SD2 in the vertical direction Z. In this case, because the second upper source/drain region SD2 is electrically connected to a second upper contact merged line, a second upper contact needs to be formed between the second upper source/drain region SD2 and the second upper contact merged line. Accordingly, to form both an upper contact and an upper contact merged line, several photolithography processes and etching processes are needed. In addition, in a middle-of-line (MOL) region in which the upper contact and the upper contact merged line are formed, a spare space is insufficient because of a demand for improvement of the integration of the multi-stack semiconductor device 10.

To solve the insufficient spare space, in the multi-stack semiconductor device 10 of the present disclosure, a process of forming the upper contact merged line may be omitted, and the dielectric cover structure DCS may be disposed between the first upper source/drain region SD2 and the first upper contact CA2 to provide the same electrical connection only with the first and second upper contacts CA2. Accordingly, integration may be further improved through ensuring the space of the MOL region while simplifying a manufacturing process (omitting a process of forming the upper contact merged line). In addition, even when neighboring wiring lines are affected by forming the dielectric cover structure DCS, the affection may be offset through a design of the front wiring line FML using the ensured MOL region.

Eventually, in the multi-stack semiconductor device 10 of the present disclosure, the first upper source/drain region SD2 may be capped by the dielectric cover structure DCS to improve integration and electrical performance through ensuring the space of the MOL region.

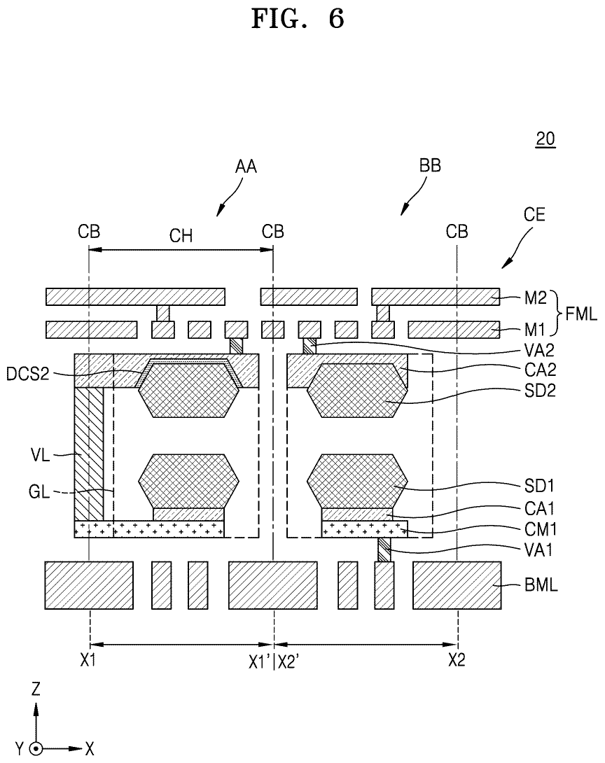

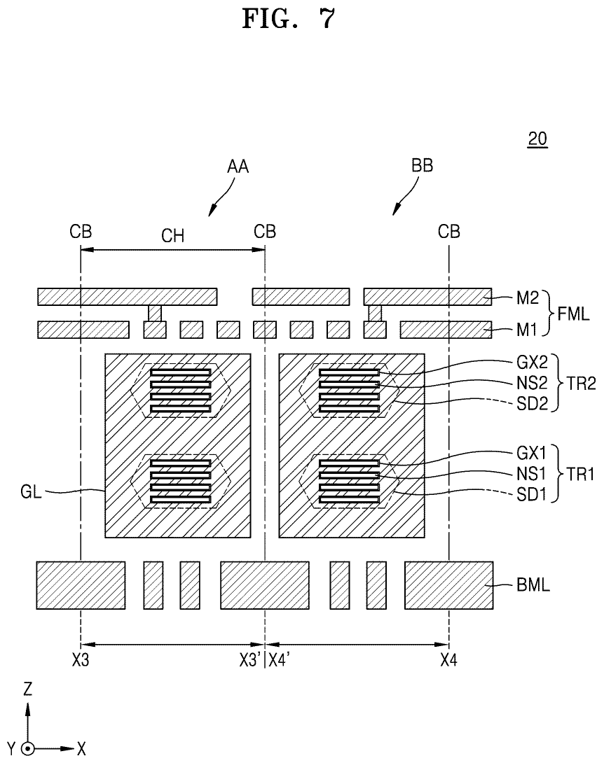

FIGS. 6 and 7 are cross-sectional views illustrating a multi-stack semiconductor device 20 according to another implementation.

Most components constituting the multi-stack semiconductor device 20 described below and materials forming the components are substantially the same as or similar to those described with reference to FIGS. 1 to 5. Therefore, for convenience of description, differences from the multi-stack semiconductor device 10 described above are mainly described.

Particularly, FIG. 6 corresponds to both a cross-section taken along the line X1-X1′ of FIG. 1 and a cross-section taken along the line X2-X2′ of FIG. 1. FIG. 7 corresponds to both a cross-section taken along the line X3-X3′ of FIG. 1 and a cross-section taken along the line X4-X4′ of FIG. 1.

Referring to FIGS. 6 and 7, the multi-stack semiconductor device 20 of the present disclosure may include a plurality of cells CE, and each cell CE may include a plurality of lower transistors TR1 and a plurality of upper transistors TR2.

In the multi-stack semiconductor device 20 of the present disclosure, a cross-section of each of first and second upper source/drain regions SD2 may have a hexagonal shape, and a dielectric cover structure DCS2 may be conformally formed to cover a portion of both upper side surfaces and all of the upper surface of the hexagonal shape of the first upper source/drain region SD2.

In the multi-stack semiconductor device 20 of the present disclosure, the shape of the first and second upper source/drain regions SD2 may be the same as the shape of first and second lower source/drain regions SD1. That is, a cross-section of each of the first and second lower source/drain regions SD1 may have a hexagonal shape.

However, in the multi-stack semiconductor device 20 of the present disclosure, the shape of the first and second lower source/drain regions SD1 and the shape of the first and second upper source/drain regions SD2 are not limited thereto. For example, both the shape of the first and second lower source/drain regions SD1 and the shape of the first and second upper source/drain regions SD2 may be quadrangular shapes (e.g., rectangular shapes).

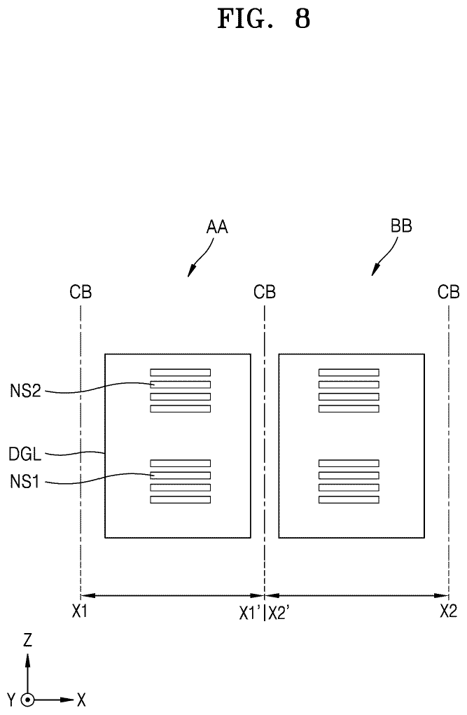

FIGS. 8 to 14 are cross-sectional views illustrating, in a process order, a method of manufacturing a multi-stack semiconductor device, according to an implementation.

For convenience of description and convenience of understanding, some components not shown on a cross-section in the cross-sectional views of FIGS. 8 to 14 are shown in a projection manner. In addition, the projected components in the cross-sectional views are shown by a dashed line.

Referring to FIG. 8, a plurality of lower nanosheets NS1 may be formed on a semiconductor substrate (not shown). Although not shown in FIG. 8, a lower dielectric layer surrounding the plurality of lower nanosheets NS1 may be formed together.

Next, a plurality of upper nanosheets NS2 may be formed to be spaced apart from the plurality of lower nanosheets NS1 in the vertical direction Z. Although not shown in FIG. 8, an upper dielectric layer surrounding the plurality of upper nanosheets NS2 may be formed together. In addition, an intermediate dielectric layer may be formed between the plurality of lower nanosheets NS1 and the plurality of upper nanosheets NS2.

Next, a plurality of dummy gate lines DGL, each surrounding the plurality of lower nanosheets NS1 and the plurality of upper nanosheets NS2, may be formed. The plurality of dummy gate lines DGL may be formed using at least one of silicon oxide, silicon nitride, polysilicon, and spin-on hardmask. In some implementations, each of the plurality of dummy gate lines DGL may have a dual-layer structure including different materials.

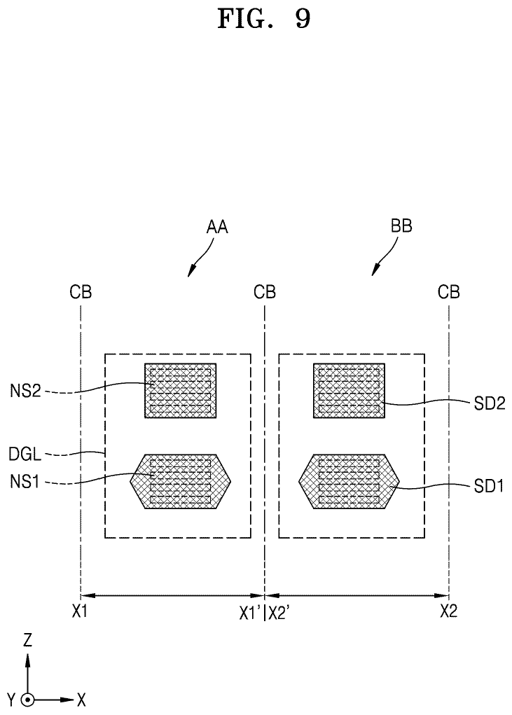

Referring to FIG. 9, a lower source/drain region SD1 may be formed using an epitaxy growth process on the result of FIG. 8. The lower source/drain region SD1 may be connected to both ends of the plurality of lower nanosheets NS1. Herein, the lower source/drain region SD1 may be formed in a hexagonal shape.

Next, an upper source/drain region SD2 may be formed using the epitaxy growth process. The upper source/drain region SD2 may be connected to both ends of the plurality of upper nanosheets NS2. Herein, the upper source/drain region SD2 may be formed in a quadrangular shape. The difference between the shape of the lower source/drain region SD1 and the shape of the upper source/drain region SD2 may be caused by the difference between materials used in the epitaxy growth process and/or the difference between doping concentrations.

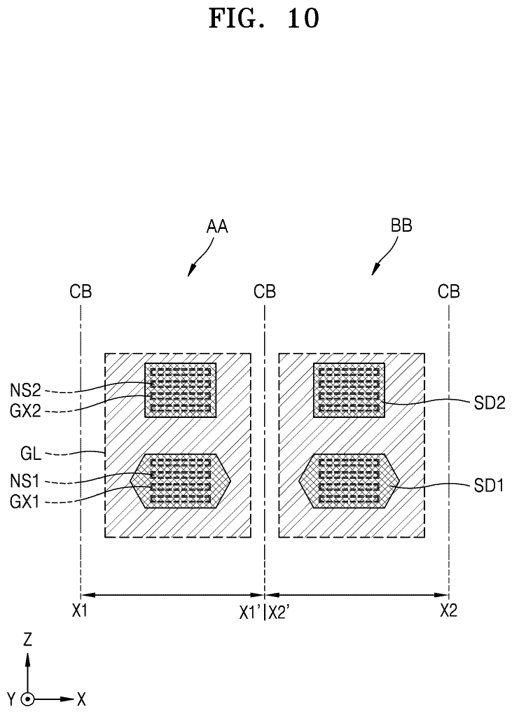

Referring to FIG. 10, the plurality of dummy gate lines DGL may be removed from the result of FIG. 9, and the surface of each of the plurality of lower nanosheets NS1 and the plurality of upper nanosheets NS2 may be exposed.

Next, a plurality of lower gate dielectric layers GX1 respectively surrounding the plurality of lower nanosheets NS1 and a plurality of upper gate dielectric layers GX2 respectively surrounding the plurality of upper nanosheets NS2 may be formed. The plurality of lower gate dielectric layers GX1 and the plurality of upper gate dielectric layers GX2 may be formed simultaneously or sequentially.

Next, a plurality of gate lines GL may be formed in the space from which the plurality of dummy gate lines DGL are removed. Each of the plurality of gate lines GL may include a work function metal-containing layer (not shown) and a gap-fill metal layer (not shown). Materials forming the work function conductive layer and the buried conductive layer are the same as described above.

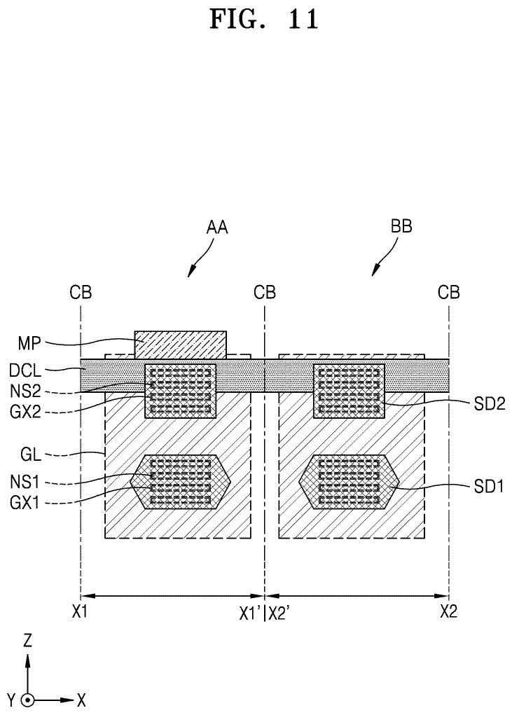

Referring to FIG. 11, a dielectric cover line DCL may be formed on the upper source/drain region SD2 of the result of FIG. 10. The dielectric cover line DCL may include a dielectric material, such as silicon nitride, silicon carbide, or silicon carbonitride, having an etching selectivity with respect to silicon oxide.

Next, a mask pattern MP may be formed on the dielectric cover line DCL so as to overlap a first upper source/drain region SD2 in the vertical direction Z. The mask pattern MP may be a photoresist pattern. The mask pattern MP may be formed using a photolithography process and a development process. In the first horizontal direction X, the width of the mask pattern MP may be greater than the width of the first upper source/drain region SD2.

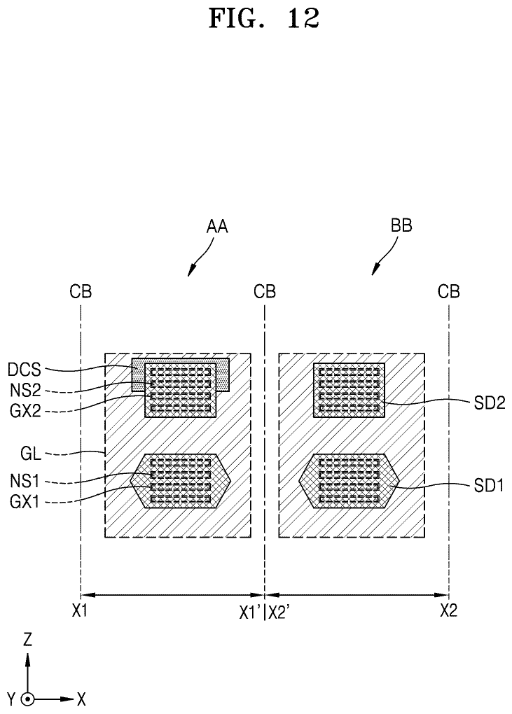

Referring to FIG. 12, a dielectric cover structure DCS may be formed on the first upper source/drain region SD2 by using the mask pattern MP as an etching mask to etch the dielectric cover line DCL in the result of FIG. 11. However, the dielectric cover structure DCS may not be formed on a second upper source/drain region SD2.

Particularly, only a desired portion of the dielectric cover line DCL may be removed by an etching process by using an etching selectivity with respect to silicon oxide that is a dielectric material around the dielectric cover structure DCS. Accordingly, the dielectric cover structure DCS conformally covering the upper surface and a portion of both sidewalls of the first upper source/drain region SD2 may be formed.

Next, the mask pattern MP (see FIG. 11) may be removed using an ashing process and a strip process.

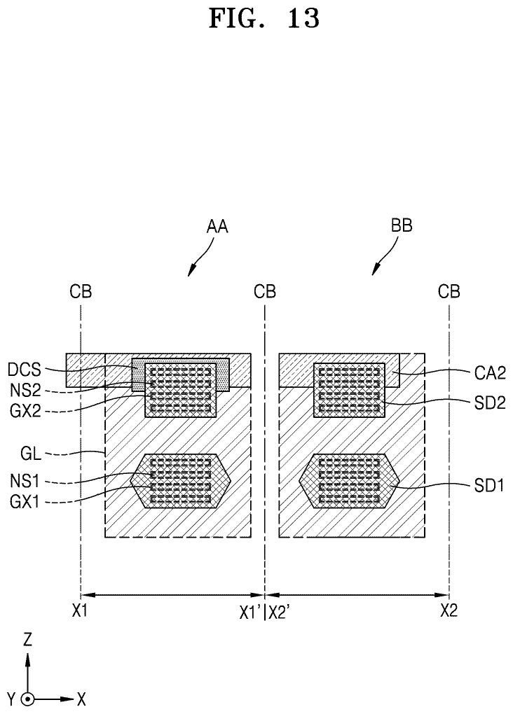

Referring to FIG. 13, first and second upper contacts CA2 may be respectively formed on the dielectric cover structure DCS and the second upper source/drain region SD2 in the result of FIG. 12. The first and second upper contacts CA2 may be formed in the same process operation.

In the area AA of FIG. 13, by the dielectric cover structure DCS, the first upper source/drain region SD2 and the first upper contact CA2 may not be in contact with each other and not be electrically connected to each other. However, in the area BB of FIG. 13, the second upper source/drain region SD2 and the second upper contact CA2 may be in contact with each other and be electrically connected to each other.

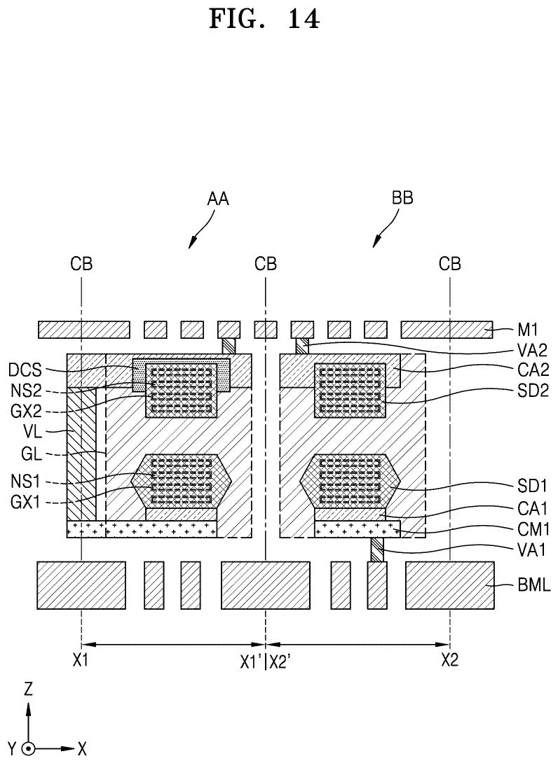

Referring to FIG. 14, an upper via VA2, which is in contact with the upper contact CA2 in the result of FIG. 13, and a first wiring line M1 may be formed, the semiconductor substrate (not shown) may be upside down and removed, and then a vertical conductive via VL may be formed.

Next, a lower contact CA1, which is in contact with the lower source/drain region SD1, and a lower contact merged line CM1, which is in contact with the lower contact CA1 and the vertical conductive via VL, may be formed. Although not shown in FIG. 14, a plurality of dielectric layers, each surrounding the lower contact CA1 and the lower contact merged line CM1, may be formed.

Next, a lower via VA1, which is in contact with the lower contact merged line CM1, and a back wiring line BML may be formed. Although not shown in FIG. 14, a plurality of dielectric layers, each surrounding the back wiring line BML, may be formed.

Referring back to FIG. 2, the multi-stack semiconductor device 10 of the present disclosure may be manufactured by forming the second wiring line M2 on the first wiring line M1 to form the front wiring line FML.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A multi-stack semiconductor device comprising:
first and second lower source/drain regions;
first and second lower contact structures on lower surfaces of the first and second lower source/drain regions, respectively;
first and second upper source/drain regions being vertically spaced apart from the first and second lower source/drain regions, respectively;
first and second upper contacts on upper surfaces of the first and second upper source/drain regions, respectively;
a vertical conductive via vertically connecting the first lower contact structure to the first upper contact; and
a dielectric cover structure between the first upper source/drain region and the first upper contact,
wherein the first upper source/drain region and the first upper contact overlap and are spaced apart from each other in a vertical direction and a horizontal direction, and wherein the second upper source/drain region and the second upper contact overlap and are in contact with each other in the vertical direction and the horizontal direction.

2. The multi-stack semiconductor device of claim 1, comprising a front wiring line connecting the first upper contact to the second upper contact,
wherein the first lower source/drain region is electrically connected to the second upper source/drain region through the first lower contact structure, the vertical conductive via, the first upper contact, the front wiring line, and the second upper contact.

3. The multi-stack semiconductor device of claim 1, wherein a vertical level of a lowermost surface of the first upper contact is lower than a vertical level of an uppermost surface of the first upper source/drain region, and a vertical level of an uppermost surface of the first upper contact is higher than the vertical level of the uppermost surface of the first upper source/drain region.

4. The multi-stack semiconductor device of claim 1, wherein the horizontal direction is a first horizontal direction, and the first upper contact extends lengthwise in the first horizontal direction,
wherein in the first horizontal direction, a length of the dielectric cover structure is less than a length of the first upper contact, and the length of the dielectric cover structure is greater than a length of the first upper source/drain region,
wherein in a second horizontal direction that intersects the first horizontal direction, a width of the dielectric cover structure is greater than a width of the first upper contact, and the width of the dielectric cover structure is less than a width of the first upper source/drain region.

5. The multi-stack semiconductor device of claim 4, comprising a pair of gate lines at opposite sides of the first upper source/drain region, respectively,
wherein the width of the dielectric cover structure is less than or equal to a gap distance between the pair of gate lines.

6. The multi-stack semiconductor device of claim 4, wherein, in the first horizontal direction, the length of the first upper contact is greater than a length of the second upper contact.

7. The multi-stack semiconductor device of claim 1, wherein a cross-section of each of the first and second upper source/drain regions has a quadrangular shape, and
wherein the dielectric cover structure covers a portion of a first side surface, a portion of a second side surface, and an upper surface of the quadrangular shape of the first upper source/drain region.

8. The multi-stack semiconductor device of claim 1, wherein a cross-section of each of the first and second upper source/drain regions has a hexagonal shape, and
wherein the dielectric cover structure covers at least a portion of a first upper side surface, at least a portion of a second upper side surface, and an uppermost surface of the hexagonal shape of the first upper source/drain region.

9. The multi-stack semiconductor device of claim 1, comprising a gate line between the first upper source/drain region and the second upper source/drain region,
wherein a first sidewall of the gate line faces the dielectric cover structure, and a second sidewall of the gate line is opposed to the first sidewall and offset from the dielectric cover structure.

10. The multi-stack semiconductor device of claim 9, wherein the first sidewall of the gate line is in contact with the dielectric cover structure.

11. A multi-stack semiconductor device comprising:
first and second lower source/drain regions;
first and second lower contact structures on lower surfaces of the first and second lower source/drain regions, respectively;
first and second upper source/drain regions being vertically spaced apart from the first and second lower source/drain regions, respectively;
first and second upper contacts on upper surfaces of the first and second upper source/drain regions, respectively;
a vertical conductive via vertically connecting the first lower contact structure to the first upper contact; and
a dielectric cover structure between the first upper source/drain region and the first upper contact,
wherein the first upper source/drain region, the dielectric cover structure, and the first upper contact overlap in a horizontal direction at a same vertical level.

12. The multi-stack semiconductor device of claim 11, comprising a front wiring line connecting the first upper contact to the second upper contact,
wherein the first lower contact structure comprises a first lower contact and a first lower contact merged line,
wherein the first lower source/drain region is electrically connected to the second upper source/drain region through the first lower contact, the first lower contact merged line, the vertical conductive via, the first upper contact, the front wiring line, and the second upper contact, and
wherein the first lower source/drain region is insulated from the first upper source/drain region by the dielectric cover structure.

13. The multi-stack semiconductor device of claim 11, wherein the first upper contact comprises a lower surface that has an uneven structure, and the lower surface of the first upper contact covers a first side surface, a second side surface, and an upper surface of the dielectric cover structure, and
wherein the second upper contact comprises a lower surface that has an uneven structure, and the lower surface of second upper contact covers a first side surface, a second side surface, and an upper surface of the second upper source/drain region.

14. The multi-stack semiconductor device of claim 13, wherein a first thickness in a vertical direction of a portion of the first upper contact that overlaps the first upper source/drain region is less than a second thickness in the vertical direction of a portion of the second upper contact that overlaps the second upper source/drain region.

15. The multi-stack semiconductor device of claim 14, wherein vertical levels of lowermost surfaces of the first and second upper contacts are lower than vertical levels of uppermost surfaces of the first and second upper source/drain regions, respectively, and
wherein vertical levels of uppermost surfaces of the first and second upper contacts are higher than the vertical levels of the uppermost surfaces of the first and second upper source/drain regions, respectively.

16. A multi-stack semiconductor device comprising:
first and second lower source/drain regions;
first and second lower contacts on lower surfaces of the first and second lower source/drain regions, respectively;
first and second lower contact merged lines on lower surfaces of the first and second lower contacts;
first and second upper source/drain regions being vertically spaced apart from the first and second lower source/drain regions, respectively;
first and second upper contacts on upper surfaces of the first and second upper source/drain regions, respectively;
a vertical conductive via vertically connecting the first lower contact merged line to the first upper contact;
a front wiring line connecting the first upper contact to the second upper contact; and
a dielectric cover structure between the first upper source/drain region and the first upper contact,
wherein the first lower source/drain region is electrically connected to the second upper source/drain region through the first lower contact, the first lower contact merged line, the vertical conductive via, the first upper contact, the front wiring line, and the second upper contact, and
wherein the first lower source/drain region is insulated from the first upper source/drain region by the dielectric cover structure.

17. The multi-stack semiconductor device of claim 16, comprising:
a first gate line between the first and second upper source/drain regions, the first gate line being at a first side of the first upper source/drain region and at a first side of the second upper source/drain region;
a second gate line at a second side of the first upper source/drain region; and
a third gate line at a second side of the second upper source/drain region,
wherein the dielectric cover structure is between the first and second gate lines, and a space between the first and third gate lines is free of the dielectric cover structure.

18. The multi-stack semiconductor device of claim 17, wherein a first sidewall of the first gate line faces the dielectric cover structure, and a second sidewall of the first gate line is opposed to the first sidewall and offset from the dielectric cover structure.

19. The multi-stack semiconductor device of claim 16, wherein a vertical level of an uppermost surface of the vertical conductive via is lower than a vertical level of an uppermost surface of the first upper source/drain region, and the vertical level of the uppermost surface of the vertical conductive via is higher than a vertical level of a lowermost surface of the first upper source/drain region, and
wherein a vertical level of a lowermost surface of the vertical conductive via is lower than a vertical level of a lowermost surface of the first lower source/drain region.

20. The multi-stack semiconductor device of claim 19, wherein the uppermost surface of the vertical conductive via is in direct contact with a lowermost surface of the first upper contact, and the lowermost surface of the vertical conductive via is in direct contact with an uppermost surface of the first lower contact merged line.
